(19) United States
(12) Patent Application Publication
(10) Pub. No.: US 2006/0124956 A1
(43) Pub. Date: Jun. 15, 2006

(54) Quasi group III-nitride substrates and methods of mass production of the same

(76) Inventor: Hui Peng, Fremont, CA (US)

Correspondence Address: Hui Peng, 35964 Vivian PL, Fremont, CA, 94536, US

(21) Appl. No.: 11/010,514

(22) Filed: Dec. 13, 2004

(51) Int. Cl. H01L 33/00; H01L 21/00

(52) U.S. Cl. 257/103; 257/14; 438/22; 257/94

(57) ABSTRACT

The present invention discloses the large area high quality quasi group III-nitride substrates comprising two categories: electrically conductive and isolating. The methods manufacturing the same comprise the following process steps in the order presented: disposing a first intermediate layer on a large area silicon (Si) original growth substrate, disposing a group III-nitride epitaxial layer including a n- or p-type epitaxial layer, disposing a reflector/Ohmic layer, disposing a second intermediate layer, disposing a supporting plate, removing the silicon original growth substrate and the first intermediate layer, then the group III-nitride epitaxial layer exposed. Vertical and lateral GaN based LEDs growing on electrically conductive and isolating quasi group III-nitride substrates respectively are disclosed.

### BACKGROUND OF THE INVENTION

(1) Field of the Invention

The present invention discloses large area high quality quasi group III-nitride substrates, methods of mass production of the same, and methods of manufacturing high power vertical and lateral GaN based light emitting diodes (LEDs) thereon.

(2) Prior Art

GaN based epitaxial materials are suitable for making optoelectronic devices or chips including GaN based light emitting diodes (LEDs). Native substrates produce the best active region quality, but suffer from limited size, cost, and availability. Foreign substrates, such as sapphire and silicon carbide (SiC), suffer the most in active region quality and limited size.

High power white LEDs have potential to replace conventional light bulbs for interior lighting. But several critical issues associated with lateral GaN based LEDs need to be addressed, which include: (1) heat dissipation, (2) production cost, (3) current crowding effect, (4) output light power saturation when current density increasing, and (5) light extraction efficiency.

In order to resolve the heat dissipation issue of high power lateral GaN based LEDs on sapphire substrates, the flip chip technique is employed. But the flip chip process is complex and costly. Therefore extensive efforts are devoted on vertical GaN based LEDs. The demonstrated advantages of vertical LEDs are the following: (1) higher light extraction efficiency; (2) more uniformly distributed current; (3) higher current density without light output saturation; (4) lower series resistance and lower forward voltage; (5) higher power conversion efficiency, especially at high current; (6) higher reliability; and (7) higher heat dissipation. However, the removing process of original growth substrates damages the quality of active region of vertical GaN based LEDs.

| | | lateral LEDs | lateral LEDs | |
|---|---|---|---|---|
| | vertical | on GaN | on sapphire | |
| | LEDs | substrate | substrate | flip chip |
| current | at High | at Low | at Low | at Low |
| crowding | current | current | current | current |
| | density | density | density | density |
| current | high | low | low | low |
| density | | | | |
| rate of heat | high | high | low | medium |
| dissipation | | | | |

In order to reduce the production cost of high power LEDs, employing a large area substrate is a proven method in semiconductor industry. However, manufacturing larger area sapphire, SiC, AlN, and GaN substrates are technically difficult and costly.

Silicon (Si) wafers are inexpensive, high quality, excellent heat dissipation, large diameter, and commercially available. Therefore extensive efforts have been devoted on growing GaN based LEDs on Si wafers. The main difficulty of growing GaN based LEDs on Si wafers is attributed to the differences of the lattice constants and the thermal expansion coefficients (TEC) between the Si substrates and the GaN based epitaxial layers. Those differences cause huge stress in GaN based epitaxial layers, and further reduce the quality of the GaN based epitaxial layers.

When a large diameter Si wafer is employed, the uniformity issue is severe. Firstly, even a small temperature fluctuation will cause the significant difference in the composition and the growth rate, which results in a deviation from the target wavelength and intensity of emitted light. Secondly, even for an originally flat growth substrate which is placed on an uniformly heated susceptor of a metal organic chemical vapor deposition (MOCVD), the top surface of the original growth substrate is slightly cooler than that of the bottom surface. Therefore the original growth substrate bows, because of the differences in the temperatures of both surfaces. This, in turn, causes a loss of contact at the edges, which become progressively cooler. As a consequence, there is a radial distribution of the temperatures on the surface of the original growth substrate, and resulting a maximum shear stress. When the shear stress exceeds the critical resolved shear stress, the dislocations are generated and propagate to result in slip lines. The uniformity issue limits the size of a substrate employed.

U.S. Pat. No. 6,639,258 discloses a quasi GaN substrate by growing a GaN epitaxial layer of thickness about 100 mu.m on a sapphire substrate and then removing the substrate. However the so-grown quasi GaN substrates are costly, have small area, and can only be employed for lateral GaN based LEDs.

U.S. Pat. No. 6,649,287 discloses the method of growing GaN material on Si wafers. The so-grown quasi GaN substrates may only be applied to grow lateral GaN based LEDs.

There is no quasi GaN substrate for growing vertical GaN based LEDs which have more advantages over lateral GaN based LEDs.

There are increasing demands for large area and high quality quasi group III-nitride substrates including quasi GaN based substrates for growing high quality GaN based semiconductor chips or devices including high power vertical GaN based LEDs, without above mentioned drawbacks, and cost effective methods for mass production of the same.

### BRIEF SUMMARY OF THE INVENTION

The present invention discloses quasi group III-nitride substrates including electrically conductive and isolating substrates. Electrically conductive quasi group III-nitride substrates with several different configurations may be employed for cost-effectively manufacturing high quality high power vertical GaN based LEDs. Several different configurations of isolating quasi group III-nitride substrates, which having fast heat dissipation rate, may be employed for growing high power lateral GaN based LEDs and AlGaN/GaN based high electron mobility transistor (HEMT).

The present invention further discloses cost effective methods of manufacturing large area high quality quasi group III-nitride substrates. An embodiment of manufacturing processes comprises, in the order presented: disposing first intermediate layer on a Si substrate, growing a group III-nitride epitaxial layer, disposing a reflector/Ohmic layer, disposing a second intermediate layer, disposing a supporting substrate, removing the Si substrate and the first intermediate layer, the group III-nitride epitaxial layer exposed. The exposed group III-nitride epitaxial layer and the supporting substrate form a quasi group III-nitride substrate. The supporting substrate may be a Si wafer, an electrically conductive Si wafer, or other high thermal conductive and low TEC materials.

The advantages of employing Si substrates are the following: (1) large diameter: the largest diameter of a Si wafer now is 12″, which is equivalent to 36 sapphire substrates of 2″; therefore the processes of the epitaxial growth and wafer fabrication including photolithography, etching, and disposing electrodes, are significantly simplified and throughput and yield are higher; (2) the cost of a Si substrate is much lower than that of equivalent sapphire substrates; (3) the LEDs grown on a Si substrate may be easily integrated with Si based Integrated Circuit (IC) including the control circuits of LEDs; (4) The heat dissipation rate of a Si wafer is faster than that of a sapphire wafer, both conductive and isolating quasi group III-nitride substrates may be employed for growing high power vertical and lateral GaN based LEDs respectively.

The present invention further discloses methods of growing high power vertical and lateral GaN based LEDs on electrically conductive and isolating quasi group III-nitride substrates respectively. The same method may be applied to grow other semiconductor chips or devices.

The purposes and advantages are the following.

(1) The primary object of the present invention is to provide large area high quality quasi group III-nitride substrates with lower dislocation and distortion density. The diameter of a quasi group III-nitride substrate is the same as that of a Si wafer employed as the original growth substrate.

(2) The second object of the present invention is to provide large area high quality quasi group III-nitride substrates for growing high power vertical semiconductor chips or devices including vertical GaN based LEDs.

(3) The third object of the present invention is to provide large diameter high quality quasi group III-nitride substrates for growing high power lateral semiconductor chips or devices including lateral GaN based LEDs.

(4) The fourth object of the present invention is to provide low cost methods of manufacturing large area high quality quasi group III-nitride substrates.

(5) The fifth object of the present invention is to provide methods of manufacturing high quality high power vertical and lateral GaN based LEDs with low cost: growing GaN based LEDs on quasi group III-nitride substrates, such that the LEDs have high quality. Manufacturing vertical GaN based LEDs on electrically conductive quasi group III-nitride substrates is simpler than manufacturing a conventional lateral LED on a sapphire substrate, since there is no need to etch GaN based epitaxial layer down to n-type cladding layer and dispose an electrode thereon, thus have higher yield. The current is distributed uniformly in vertical GaN based LEDs grown on conductive quasi group III-nitride substrates. The current density is higher without light power saturation.

High power lateral LEDs grown on isolating quasi group III-nitride substrates have high heat dissipation rate, therefore there is no need to employ flip chip technique, cost of production is lowed further.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages will be best understood by referring to detailed descriptions that follow, when read in conjunction with the accompanying drawings.

FIG. 1 shows a preferred embodiment of processes of the present invention for manufacturing large diameter high quality quasi group III-nitride substrates.

FIG. 2a shows the top view of a preferred embodiment of a textured surface.

FIG. 2b shows a cross sectional views of the textured surface.

FIG. 3a is the cross sectional view of the first embodiment of electrically conductive quasi group III-nitride substrates.

FIG. 3b is the cross sectional view of the second embodiment of electrically conductive quasi group III-nitride substrates.

FIG. 3c is the cross sectional view of the third embodiment of electrically conductive quasi group III-nitride substrates.

FIG. 3d is the cross sectional view of the fourth embodiment of electrically conductive quasi group III-nitride substrates.

FIG. 3e is the cross sectional view of the first embodiment of isolating quasi group III-nitride substrates.

FIG. 3f is the cross sectional view of the second embodiment of isolating quasi group III-nitride substrates.

FIG. 3g is the cross sectional view of the third embodiment of isolating quasi group III-nitride substrates.

FIG. 3h is the cross sectional view of the fourth embodiment of isolating quasi group III-nitride substrates.

FIG. 4a shows a cross sectional view of a preferred embodiment of a vertical GaN based LED grown on an electrically conductive quasi group III-nitride substrate.

FIG. 4b shows a cross sectional view of a preferred embodiment of a lateral group III-nitride LED grown on an isolating quasi Group III-nitride substrate.

FIG. 5 shows room temperature bandgap energy versus lattice constant of elements and compound semiconductors.

### DETAILED DESCRIPTION OF THE INVENTION

While embodiments of the present invention will be described below, those skilled in the art will recognize that other manufacturing processes and other quasi group III-nitride substrates are capable of implementing the principles of the present invention. Thus the following description is illustrative only and not limiting.

Reference is specifically made to the drawings wherein like numbers are used to designate like members throughout.

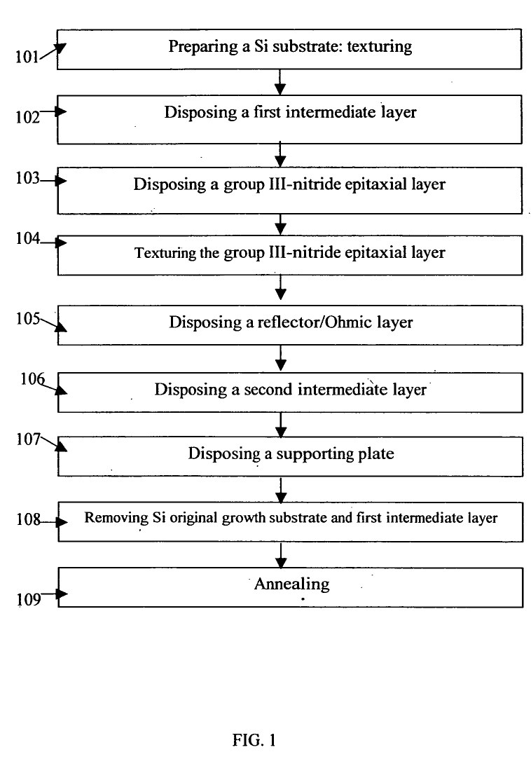

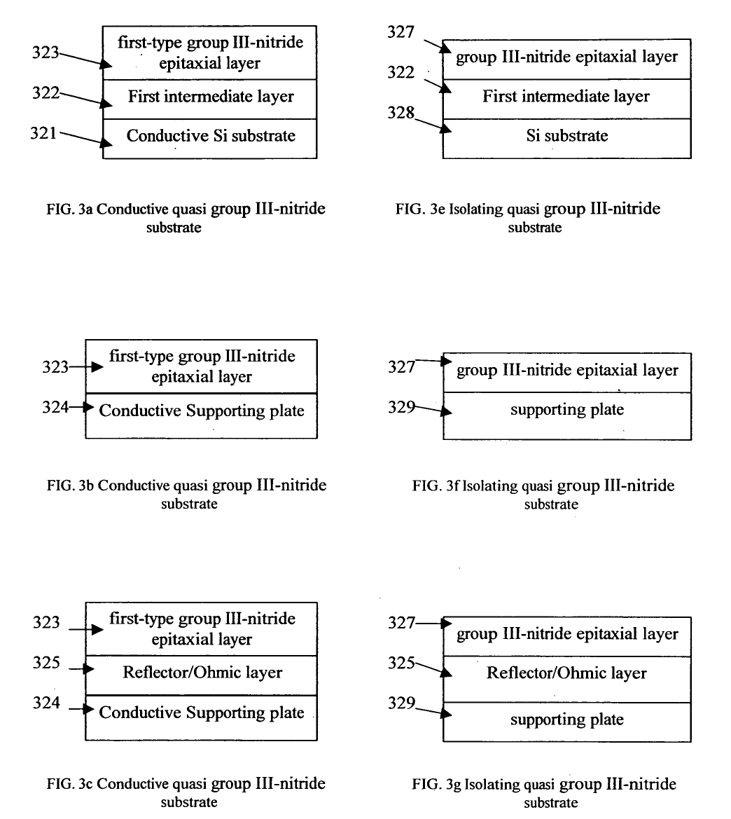

Note the followings:
(1) FIG. 1 shows a preferred embodiment of processes of manufacturing large area high quality quasi group III-nitride substrates. The preferred embodiment of processes is employed to manufacture both electrically conductive and isolating quasi group III-nitride substrates. Partial of process steps of the preferred embodiment are also capable for manufacturing different configurations of large area high quality quasi group III-nitride substrates, such as quality quasi group III-nitride substrates of FIG. 3a to 3c and 3e to 3g. The processes may be employed to manufacture other quasi substrates.
(2) A “group III-nitride epitaxial layer” in the present invention stands for: (a) binary, ternary, and quaternary alloys of elements gallium (Ga), aluminum (Al), boron (B), indium (In), nitrogen (N), comprising GaN, AlN, InN, BAlN, BGaN, AlGaN, InGaN, AlInGaN; and (b) first-type of the above binary, ternary, and quaternary alloys, comprising n- or p-type GaN, n- or p-type AlGaN.
(3) The structures of a group III-nitride epitaxial layer is selected from a group comprising single layer structure, multiple layer structure, and compositionally graded structure that is the following: at the different depth of the epitaxial layer, the ratios of chemical compositions are different
(4) The “group III-nitride substrate” in the present invention stands for a substrate having a group III-nitride epitaxial layer disposed on it. Wherein the substrate is selected from a group comprising original growth substrates and supporting substrates.
(5) The original growth substrates for manufacturing quasi group III-nitride substrates are selected from a group comprising electrically isolating silicon (Si) wafers and electrically conductive Si wafers. The crystal planes of the employed Si original growth wafers comprise (001) and (111).
(6) One side of a Si original growth substrate of the present invention may be textured before growing group III-nitride epitaxial layers. U.S. patent application Ser. No. 10/723,046 discloses textured substrates. The texturing methods comprise wet and dry etch. An embodiment of the wet etch is to employ NHO.sub.3 and HF to etch Si substrates.
(7) For avoiding bowed original growth substrates during the growth of group III-nitride epitaxial layers, several methods may be applied, which comprise: (a) non-rigid holding an original growth substrate to a high thermal conductivity plate; wherein the material of the plate comprises molybdenum (Mo); wherein the methods of non-rigid holding comprise bonding by Au, solders, low melting point metal, non-rigid mechanical fixture, and combination thereof; (b) heating the top surface of the original growth substrate by infrared heat source; (c) combinations of above methods. The above methods may also be employed during the growth of semiconductor devices or chips on quasi group III-nitride substrates.
(8) The first intermediate layer of the present invention comprises two categories, one is an electrically conductive first intermediate layer, and the other is an electrically isolating first intermediate layer.
(9) The structures of a first intermediate layer of the present invention comprise one layer and multiple layer structures.
(10) The materials of each layer of the first intermediate layer of the present invention is selected from a group comprising:
   (a) An epitaxial layer; wherein the material of each layer of the epitaxial layer is selected from a group comprises binary, ternary, and quaternary of elements of nitrogen (N), phosphorus (P), boron (B), silicon (Si), carbon (C), aluminum (Al), gallium (Ga), comprising AlN, BP, 6H—SiC, 3C—SiC, BAlN, AlGaN, and combinations thereof; wherein the epitaxial layer is disposed by methods comprising MBE or MOCVD;
   (b) a low melting point metal layer; wherein the material of the layer is selected from a group comprising cadmium (Cd), indium (In), and tin (Sn); wherein the low melting point metal layer is disposed by methods comprising vacuum evaporation; wherein low melting point metals have melting point lower than the temperature of epitaxial growth;
   (c) a high melting point metal layer; the material of the high melting point metal layer is selected from a group comprising hafnium (Hf), scandium (Sc), titanium (Ti), vanadium (V), chromium (Cr), gold (Au), zirconium (Zr); the high melting point metals having melting point higher than the temperature of epitaxial growth;
   (d) a nitride layer of said high melting point metals; the nitride layer comprising HfN, ScN, and TiN;
   (e) combinations of (a), (b), (c), and (d).
(11) The methods of disposing a nitride layer of high melting point metals comprise disposing the nitrides of high melting point metals and nitriding the top surface of the high melting point metal layers.
(12) The structures of the epitaxial layer of a first intermediate layer of the present invention comprise single layer structure, multiple layer structure, and compositionally graded structure; wherein a compositionally graded structure is the following: at the different depth of an epitaxial layer, the ratios of chemical compositions are different.

An embodiment is the following: the ratio of chemical compositions of the top layer of the first intermediate layer is so selected that the difference of the lattice constants between the top layer of the first intermediate layer and the group III-nitride epitaxial layer grown on the top surface of the first intermediate layer is minimized, thus the stress in the group III-nitride epitaxial layer is minimized.
(13) The methods of growing the epitaxial layer of a first intermediate layer comprise two-step-method which is the following: growing the first intermediate layer under a Ga-lean condition first, then growing at Ga-rich condition, so that the epitaxial layer of the first intermediate layer have high quality.

(14) The functions of a low melting point metal layer in a first intermediate layer are the following: (a) when growing the other epitaxial layers of the first intermediate layer and a group III-nitride epitaxial layer, the low melting point metal layer molten, the whole first intermediate layer is stick to the Si substrate by the surface tension, thus, the heat is uniformly transferred to the whole epitaxial layer by the melting metal. (b) When the epitaxial growth completed and cooling down to about 160 degree C. (the melting point for indium is 157 degree C.), the low melting point metal becomes solid, then the temperature continuously cools down to room temperature of about 20 degree C. At a range of about 140 degree C., the difference of the TEC between the epitaxial layer and the substrate causes a small stress in the epitaxial layer, thus the epitaxial layer has high quality. (c) At the process of removing Si original growth substrate, by heating up to the melting point, the low melting point metal melts, the Si original growth substrate and the epitaxial layer are separated by shearing.
(15) Coating a thin layer of Al on the Si original growth substrate before disposing an epitaxial layer of the first intermediate layer will prevent the formation of silicon nitride and, thus improve the quality of the epitaxial layer.
(16) A group III-nitride epitaxial layer grows on the top surface of either the first intermediate layer or the original growth substrate.
(17) The structures of a group III-nitride epitaxial layer of the present invention comprise compositionally graded structure.

An embodiment is the following: the ratio of chemical compositions of the bottom layer of the group III-nitride epitaxial layer is so selected that the difference of the lattice constants between the bottom layer of the group III-nitride epitaxial layer and the top layer of the first intermediate layer is minimized.
(18) The methods of growing a group III-nitride epitaxial layer comprise two-step-method which is the following: growing the group III-nitride epitaxial layer under a Ga-lean condition first, then growing under a Ga-rich condition, so that the group III-nitride epitaxial layer have high quality.
(19) A reflector/Ohmic layer disposed on a group III-nitride epitaxial layer comprises single layer structure and multiple layer structure. A reflector/Ohmic layer of the present invention may also be a Distributed Bragg reflector (DBR).
(20) Quasi group III-nitride substrates with reflector/Ohmic layer are for applications of growing LEDs. Reflector/Ohmic layer is not needed for other applications, such as HEMT.
(21) The material of each layer of a reflector/Ohmic layer is selected from a group comprising gold (Au), nickel (Ni), rhodium (Rh), titanium (Ti), platinum (Pt), copper (Cu), silver (Ag), vanadium (V), aluminum (Al), chromium (Cr), their alloys, and combinations thereof, such as Au/Ni/Ti.
(22) The structure of second intermediate layer comprises one layer and multiple layers. The material of a second intermediate layer is selected from d a group comprising indium (In), cadmium (Cd), tin (Sn), and low melting point alloys comprising AuSn and AuGe. Second intermediate layer may be disposed by methods comprising vacuum evaporation.
(23) The functions of a second intermediate layer are: (a) when growing a group III-nitride epitaxial layer including a GaN based epitaxial layer on a quasi group III-nitride substrate, the second intermediate layer molten, the whole group III-nitride epitaxial layer is stick to the supporting substrate by the surface tension and air pressure, thus, the heat is uniformly transferred to the group III-nitride epitaxial layer by the melting metal. (b) When the growth of the group III-nitride epitaxial layer completed and cooling down to about 160 degree C., the low melting point metal becomes solid, the temperature continuously cools down to room temperature of about 20 degree C. At a range of about 140 degree C., the difference of the TEC between the group III-nitride epitaxial layer and the supporting substrate causes a small stress in the group III-nitride epitaxial layer, thus the group III-nitride epitaxial layer has high quality.
(24) The material of a supporting substrate is selected from a group comprising: (a) metal plates including copper, gold, aluminum, and tungsten, (b) electrically conductive Si wafers, (c) isolating Si wafers, and (d) isolating thin films having melting points higher than that of the epitaxial layer growth temperature and having TEC matching that of group III-nitride epitaxial layers, such as AlN ceramic.
When an AlN ceramic is selected as a supporting substrate, a second intermediate layer is no longer needed, since the AlN ceramic and AlN/GaN epitaxial layer have similar TECs.
(25) The processes for removing the original growth substrate and first intermediate layer are the following: (a) when there is no low melting point metal layer in the first intermediate layer, methods of removing comprise precisely grinding and lapping/polishing, selective etching, and their combination. The precisely grinding and lapping/polishing may be controlled to a predetermined thickness with a tolerance of +/−1 um.m. The processes of etching Si original growth substrates and group III-nitride materials are quite standard now. The ICP-RIE dry etching of group III-nitride materials with BCl.sub.3/Cl.sub.2 may be employed. (b) When there is a low melting point metal layer in the first intermediate layer, an embodiment of methods of removing is to heat up to exceed the melting point, the low melting point metal melts, shearing to separate the epitaxial layer and the original growth substrate. Then selective etching is employed to remove other layers of the first intermediate layer until the group III-nitride epitaxial layer is exposed.
(26) Since vertical GaN based semiconductor chips or devices are grown on quasi group III-nitride substrates, the removing process of original growth substrates has no effects on the crystal quality and electrical-optical properties of the vertical GaN based semiconductor chips and devices.
(27) The material systems of the active layer of GaN based LEDs of the present invention comprise binary, ternary, and quaternary alloys of elements nitrogen (N), phosphorus (P), boron (B), aluminum (Al), gallium (Ga), indium (In), arsenic (As), such as GaN, AlGaN, InGaN, AlInGaN, InGaNP, and AlInGaNP; wherein InGaNP and AlInGaNP have been disclosed for white LEDs.
(28) The structures of the GaN based LEDs comprise p-n junction and double hetero-junction structures.
(29) The structures of the active layers of the GaN based LEDs comprise bulk, single quantum well, and multi quantum well.
(30) An embodiment of an annealing process is the following: at about 500-1000 degree C. in a nitrogen environment. The annealing process will recover the damage attributed to the etching process and also partially recover the dislocations. The dislocations are mainly generated at the interface between a Si original growth substrate and a first intermediate layer, and some of the dislocations propagate up into rest of the first intermediate layer and into the group III-nitride epitaxial layer including first-type group III-nitride epitaxial layer. The dislocations are held by a stress attributed to the lattice constant and TEC mismatch, once the Si original growth substrate and the first intermediate layer are removed, the stress is no longer exist to hold the dislocations in either group III-nitride epitaxial layers or first-type group III-nitride epitaxial layers. Therefore under the proper annealing condition, some of the dislocations are eliminated and those atoms are back to normal crystal structural position, i.e., the exposed group III-nitride epitaxial layer or exposed first-type group III-nitride epitaxial layer now have low dislocation density.
(31) The optimized patterns of the second electrode of a vertical GaN based LED distribute current more uniformly over the surface of the LED, thus the crowding effect is reduced, the current density is higher without light power saturation, the more material of the active layer is utilized, the LED is brighter. U.S. patent application Ser. No. 10/862,086 discloses the details of optimized patterns of the second electrode of a vertical GaN based LED.

FIG. 1 shows an embodiment of processes of the present invention for manufacturing quasi group III-nitride substrates. The embodiment of processes of the present invention is employed to manufacture both electrically conductive and isolating quasi group III-nitride substrates.

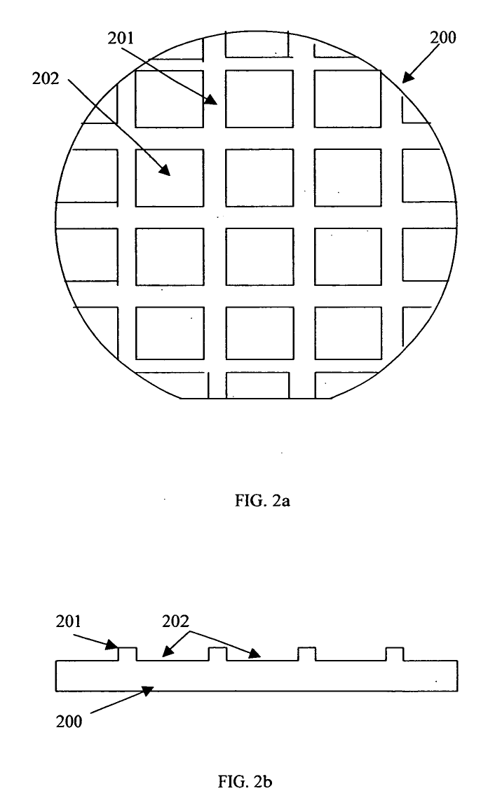

Process 101: texturing one side of a Si original growth substrate. FIG. 2 shows the details of an embodiment of the textures. Textured surface minimizes and localize the stress attributed to the difference of the TEC between the Si original growth substrate and a first intermediate layer. Therefore the dislocation and distortion densities are reduced, the quality of the epitaxial layer is higher.

The surfaces of an original growth substrate may not be textured.

In order to avoid the Si original growth substrate bowed during the epitaxial growth, and be able to employ large diameter Si original growth substrates, the following methods may be employed: (a) non-rigid holding the Si original growth substrate on a high thermal conductivity block; wherein the material of the block comprises molybdenum (Mo); wherein the methods of non-rigid holding comprise bonding by low melting point metal, non-rigid mechanical fixture, or combination thereof; (b) heating the top surface of the original growth substrate by infrared heating device; (c) employing a thicker Si original growth substrate; (d) combinations of above methods (a), (b), (c).

Process 102: disposing a first intermediate layer on the surface of a Si original growth substrate. The most critical issue of growing a group III-nitride epitaxial layer on a Si original growth substrate is the differences of the TECs and the lattice constants between them. The first intermediate layer reduces the stress caused by the above differences.

First embodiment of process 102: the first intermediate layer is an AlN layer. Disposing an AlN epitaxial layer on the surface of a Si (111) original growth substrate. The Si original growth substrate is placed in the chamber of MOCVD, at atmospheric pressure, introducing trimethylaluminum (TMA), NH.sub.3, heating up to 1000-1250 degree C., growing an AlN layer of thickness 1-500 nm with a smooth surface.

Second embodiment of process 102: the first intermediate layer is an AlN/Al layer. Disposing an Al layer of thickness of few monolayers to nanometers on the surface of a Si (111) original growth substrate for preventing the top surface of the Si original growth substrate from nitriding. Then disposing an AlN layer on the Al layer under the same condition as that of the first embodiment of process 102.

Third embodiment of process 102: nitriding the top surface of an Al layer. Firstly disposing an Al layer on the surface of a Si (111) original growth substrate. Introducing nitrogen source, heating up to 400-700 degree C. for 10-40 minutes, the top surface of the Al layer forms an AlN layer. Wherein the nitrogen sources comprise N.sub.2 and NH.sub.3/H.sub.2.

Fourth embodiment of process 102: the first intermediate layer is an B.sub.xAl.sub.1-xN layer having compositional graded structure on the surface of a Si(111) original growth substrate: placing the Si original growth substrate in MOCVD, at atmosphere pressure, heat up to 1050-1150 degree C., introducing TMA, triethylboron (TEB), NH.sub.3, disposing B.sub.xAl.sub.1-xN (0≦x<1). Selecting the value of “x” such that the difference of lattice constants between the Si original growth substrate and the BAlN layer is minimized. Then gradually decreasing the flow rate of TEB, increasing the flow rate of TMA, until x=0, i.e., transfer from growing B.sub.xAl.sub.1-xN to grow AlN. The change of value of “x” may be either continuous or discrete.

Fifth embodiment of process 102: the first intermediate layer is an BAlN/Al layer. Disposing an Al layer of thickness of few monolayer to nanometers on the surface of a Si original growth substrate first, then disposing B.sub.xAl.sub.1-xN layer on the Al layer under the same condition as that of the fourth embodiment of process 102.

Sixth embodiment of process 102: the first intermediate layer is a Ti/In layer. Disposing a layer of indium on the surface of a Si original growth substrate, disposing a Ti layer on the top surface of the indium layer. The method of disposing the indium and Ti layer comprise sputtering, vacuum evaporation, MBE, and MOCVD.

Seventh embodiment of process 102: the first intermediate layer is an AlN/Ti/In layer. Disposing a layer of indium on the surface of a Si original growth substrate, disposing a Ti layer on the top of the indium layer, then disposing an AlN layer on the Ti layer. The methods of disposing the AlN layer comprise that of the first embodiment of process 102.

Note that in embodiments 6 and 7, Ti may be replaced by hafnium (Hf), scandium (Sc), vanadium (V), chromium (Cr), gold (Au), zirconium (Zr), etc. An Au/W/In layer may also be employed to replace Ti/In.

Eighth embodiment of process 102: the first intermediate layer is an AlN/TiN/Ti/In layer. As of the sixth embodiment of process 102, disposing indium and Ti layers on a Si original growth substrate, then placing the Si original growth substrate into MOCVD, heating up to 1000-1100 degree C., introducing NH.sub.3, and H.sub.2, for about 10-50 minutes, a TiN layer is formed on the top surface of the Ti layer. Then disposing an AlN layer on the TiN layer.

Ninth embodiment of process 102: the first intermediate layer is an AlN/TiN/Ti/AuGe layer. The process is the same as that of the eighth embodiment of process 102, except that disposing an AuGe layer, instead of indium, on the Si original growth substrate.

Tenth embodiment of process 102: the first intermediate layer is a GaN/AlN layer. On the AlN layers of the above embodiments, at about 400-650 degree C., disposing a low-temperature GaN layer of thickness 10-5000 angstroms as the top surface of the first intermediate layer.

Eleventh embodiment of process 102: the first intermediate layer is a GaN/AlN layer. On the AlN layers of the above embodiments, disposing a high-temperature GaN layer by employing a two-step-growth process as the following: growing a GaN layer under Ga-lean condition, the surface of the so-grown GaN layer is rough, then growing a GaN layer under Ga-rich condition, so that the final GaN layer has a smooth surface and high quality.

Process 103: disposing a group III-nitride epitaxial layer on either the first intermediate layer or the original growth substrate. The group III-nitride epitaxial layer comprises binary, ternary, and quaternary alloys of elements gallium (Ga), aluminum (Al), boron (B), indium (In), nitrogen (N), such as GaN, AlN, BAlN, BGaN, AlGaN, InGaN, AlInGaN, and first-type of the binary, ternary, and quaternary alloys above, such as first-type GaN, first-type AlGaN. A first-type group III-nitride epitaxial layer is either a n-type or a p-type group III-nitride epitaxial layer.

First embodiment of process 103: disposing a group III-nitride epitaxial layer on the first intermediate layer by two-step method. Disposing the group III-nitride epitaxial layer under a Ga-lean condition first, then under a Ga-rich condition.

Second embodiment of process 103: disposing a first-type group III-nitride epitaxial layer, for example, a n-type Al.sub.xGa.sub.1-xN, on an electrically conductive first intermediate layer. Placing an electrically conductive Si original growth wafer with the electrically conductive first intermediate layer into a molecular beam epitaxy (MBE), at 950-1050 degree C., introduce N.sub.2, NH.sub.3, SiH.sub.4, HCl, TMG, TMA, an n-type AlGaN layer is disposed on the first intermediate layer. During the epitaxial growth, selecting the value of “x” such that there is no crack. The so-grown n-type AlGaN on the electrically conductive Si original growth wafer forms the first embodiment of electrically conductive quasi Group III-nitride substrates, which may be employed for growing vertical GaN based LEDs.

Third embodiment of process 103: disposing a n-type Al.sub.xGa.sub.1-xN on an electrically conductive Si original growth substrate.

Note that: disposing an n-type group III-nitride epitaxial layer on either the first intermediate layer or the original growth substrate may be replaced by disposing a p-type group III-nitride epitaxial layer.

Process 104: wet or dry etching the top surface of the group III-nitride epitaxial layer to form a texture. The texture minimizes and localizes the stress attributed to the difference of the TEC between the group III-nitride epitaxial layer and a reflector/Ohmic layer disposed on the group III-nitride epitaxial layer.

After process 104, an annealing process may be employed.

The process steps of texturing the surfaces of a group III-nitride epitaxial layer may not be employed.

Process 105: disposing a reflector/Ohmic layer on the textured group III-nitride epitaxial layer. The methods of disposing the reflector/Ohmic layer comprise vacuum evaporation. The material of the reflector/Ohmic layer is selected from a group comprising Au, Rh, Ni, Pt, V, Ag, Al, and their alloy. For electrically isolating quasi group III-nitride substrates, reflector/Ohmic layer may also be a DBR.

Note that: (1) disposing reflector/Ohmic layers are only for quasi group III-nitride substrates on which GaN based LEDs are grown. (2) Quasi group III-nitride substrates for growing GaN based semiconductor devices or chips, such as AlGaN/GaN based high electron mobility transistor (HEMT), do not need a reflector/Ohmic layer. (3) For manufacturing electrically conductive quasi group III-nitride substrates, an electrically conductive reflector/Ohmic layer is selected.

Process 106: disposing a second intermediate layer on the reflector/Ohmic layer. The material of a second intermediate layer acting as a stress-reducing layer is selected from a group comprising low melting point metals and low melting point alloys. The structures of second intermediate layers comprise one and multiple layers. The material of a low melting point metal layer is selected from a group comprising Cd, In, and Sn. The material of a low melting point alloy layer is selected from a group comprising AuSn and AuGe. The methods of disposing the second intermediate layer comprise vacuum evaporation.

Process 107: disposing/bonding a high thermally conductive supporting substrate to the second intermediate layer. The material of the supporting substrate is selected from a group comprising electrically conductive Si wafer, Si wafer, thin metal films (such as gold and copper), and thin isolating films with TECs matching to that of group-III nitride epitaxial layers (such as AlN ceramic). The methods of disposing Si supporting substrate comprise wafer-bonding technique to bond the Si supporting substrate to the second intermediate layer. The methods of disposing a thin metal layer on the second intermediate layer comprise electroplating, electroless plating, vacuum evaporation, and wafer bonding. The methods of disposing a thin isolating layer on the second intermediate layer comprise wafer bonding.

Note that: (1) when selecting either an AlN ceramic or thin isolating films having TEC matching to that of group III-nitride epitaxial layers as a supporting substrate, there is no need to dispose a second intermediate layer. The AlN ceramic and the thin isolating films are directly bonded to either the reflector/Ohmic layer or the textured group III-nitride epitaxial layer. (2) For manufacturing electrically conductive quasi group III-nitride substrates, an electrically conductive supporting substrate is selected.

Process 108: removing the original growth substrate and the first intermediate layer.

First embodiment: there is no low melting point metal layer in the first intermediate layer, precise lapping/polishing with thickness tolerance of +/−1 micron may be employed to remove the Si original growth substrate. Then selective etching is employed to remove the first intermediate layer, until the group III-nitride epitaxial layer exposed. The total thickness of the first intermediate layer and the group III-nitride epitaxial layer are thick enough to compensate the tolerance of removing process. U.S. patent application Ser. No. 10/765,346 discloses a substrate removing process by precisely lapping/polishing.

Second embodiment: there is a low melting point metal layer in the first intermediate layer, heating up until the low melting point metal layer melt, shearing to separate the original growth Si substrate and the group III-nitride epitaxial layer. Then selective etching is employed to remove the remaining layers of the first intermediate layer, until the group III-nitride epitaxial layer exposed.

Note that the removed Si original growth substrates are reusable, and lower the production cost further.

Process 109: annealing at 400-1000 degree C. and in an N.sub.2 environment to remove the damage on the epitaxial layer attributed to the removing process 108. On the other hand, during the annealing process, the second intermediate layer melt, the group III-nitride epitaxial layer floats on the supporting substrate, there is no external force attributed to the crystal structures of either the Si original growth substrate or the supporting substrate on the both sides of the group III-nitride epitaxial layer, therefore partial structures of the group III-nitride epitaxial layer are recovered from dislocations and distortions. Between processes 101 and 108, there are may be other annealing processes.

FIG. 2a shows a top view of an embodiment of textured top surface 200 formed by etching the top surface of a layer. The patterns of textured top surface 200 comprise a well-type. The textured top surfaces may be the top surfaces of either the original growth Si substrates of process 101, or the group III-nitride epitaxial layers of process 104.

FIG. 2b is a cross sectional view of textured top surfaces 200. Textured top surface 200 has well 202 and wall-separator 201. The height of wall-separator 201 is in an order of nanometers to microns.

Textured top surface 200 will localize and minimize the stress attributed to the different in the thermal expansion coefficient between two contacted layers.

FIG. 3a shows the first embodiment of large area high quality electrically conductive quasi group III-nitride substrates of the present invention. N-type group III-nitride epitaxial layer 323 is disposed on electrically conductive first intermediate layer 322 that is disposed on electrically conductive Si original growth substrate 321. The first embodiment of electrically conductive quasi group III-nitride substrates is manufactured by process 101 to process 103. Wherein the group III-nitride epitaxial layer of process 103 is n-type group III-nitride epitaxial layer 323. Wherein Si original growth substrate 321 and first intermediate layer 322 are electrically conductive.

Note that n-type group III-nitride epitaxial layer 323 may be directly disposed on electrically conductive Si original growth substrate 321.

FIG. 3b shows the second embodiment of large area high quality electrically conductive quasi group III-nitride substrates of the present invention. N-type group III-nitride epitaxial layer 323 is disposed on supporting substrate 324. The second embodiment of electrically conductive quasi group III-nitride substrates is manufactured by process 101 to process 103 and process 107 to process 109. Wherein the group III-nitride epitaxial layer of process 103 is n-type group III-nitride epitaxial layer 323. Wherein the substrate of process 101 is electrically conductive supporting substrate 324.

FIG. 3c shows the third embodiment of large area high quality electrically conductive quasi group III-nitride substrates of the present invention. N-type group III-nitride epitaxial layer 323 is disposed on reflector/Ohmic layer 325 that is disposed on supporting substrate 324. The third embodiment of electrically conductive quasi group III-nitride substrates is manufactured by process 101 to process` 105, and process 107 to process 109. Wherein the group III-nitride epitaxial layer of process 103 is n-type group III-nitride epitaxial layer 323. Wherein the supporting substrate 324 and reflector/Ohmic layer 325 are both electrically conductive.

FIG. 3d shows the fourth embodiment of large area high quality electrically conductive quasi group III-nitride substrates of the present invention. N-type group III-nitride epitaxial layer 323 is disposed on reflector/Ohmic layer 325 that is disposed on second intermediate layer 326. Second intermediate layer 326 is disposed on supporting substrate 324. The fourth embodiment of conductive quasi group III-nitride substrates is manufactured by process 101 to process 109. Wherein the group III-nitride epitaxial layer of process 103 is n-type group III-nitride epitaxial layer 323. Wherein the supporting substrate 324, reflector/Ohmic layer 325, and second intermediate layer 326 are all electrically conductive.

Note that: (1) all of the layers of electrically conductive quasi group III-nitride substrates of FIGS. 3a to 3d are electrically conductive. (2) The embodiments of large area high quality electrically conductive quasi group III-nitride substrates of FIGS. 3a to 3d of the present invention may be employed for growing high power vertical GaN based LEDs.

FIG. 3e shows the first embodiment of large area high quality isolating quasi group III-nitride substrates of the present invention. Group III-nitride epitaxial layer 327 is disposed on first intermediate layer 322 that is disposed on Si original growth substrate 328. The first embodiment of isolating quasi group III-nitride substrates is manufactured by process 101 to process 103.

Since Si substrates have high thermal conductivity, the first embodiment of isolating quasi group III-nitride substrates may be employed for growing high power lateral GaN based LEDs without need of employing flip chip technique for packaging.

Note that at least one of the following layers, Si original growth substrate 328, first intermediate layer 322, group III-nitride epitaxial layer 327, is electrically isolating. Group III-nitride epitaxial layer 327 may be directly disposed on Si original growth substrate 328.

FIG. 3f shows the second embodiment of large area high quality isolating quasi group III-nitride substrates of the present invention. Group III-nitride epitaxial layer 327 is disposed on supporting substrate 329. The second embodiment of isolating quasi group III-nitride substrates is manufactured by process 101 to process 103 and process 107 to process 109.

With high thermally conductive supporting substrate, the second embodiment of isolating quasi group III-nitride substrates may be employed for growing high power lateral GaN based LEDs. With high thermally conductive and electrically isolating supporting substrate, such as an AlN ceramic, this embodiment of isolating quasi Group III-nitride substrates may be employed for growing AlGaN—GaN based HEMT and lateral GaN based LEDs.

Note that at least one of the following layers, supporting substrate 329 and group III-nitride epitaxial layer 327, is electrically isolating.

FIG. 3g shows the third embodiment of large area high quality isolating quasi group III-nitride substrates of the present invention. Group III-nitride epitaxial layer 327 is disposed on reflector/Ohmic layer 325 that is disposed on supporting substrate 329. The third embodiment of isolating quasi group III-nitride substrates is manufactured by processes 101 to process 105 and process 107 to process 109.

Note that at least one of the following layers, supporting substrate 329, group III-nitride epitaxial layer 327, and reflector/Ohmic layer 325, is electrically isolating.

FIG. 3h shows the fourth embodiment of large area high quality isolating quasi group III-nitride substrates of the present invention. Group III-nitride epitaxial layer 327 is disposed on reflector/Ohmic layer 325 that is disposed on second intermediate layer 326. Second intermediate layer 326 is disposed on supporting substrate 329. The fourth embodiment of isolating quasi group III-nitride substrates is manufactured by process 101 to process 109.

Note that the embodiments of FIG. 3g and 3h of large area high quality isolating quasi group III-nitride substrates of the present invention comprise a reflector/Ohmic layer and may be employed for growing high power lateral GaN based LEDs with higher light extraction efficiency.

Note that at least one of the following layers, supporting substrate 329, group III-nitride epitaxial layer 327, reflector/Ohmic layer 325, and second intermediate layer 326, is electrically isolating.

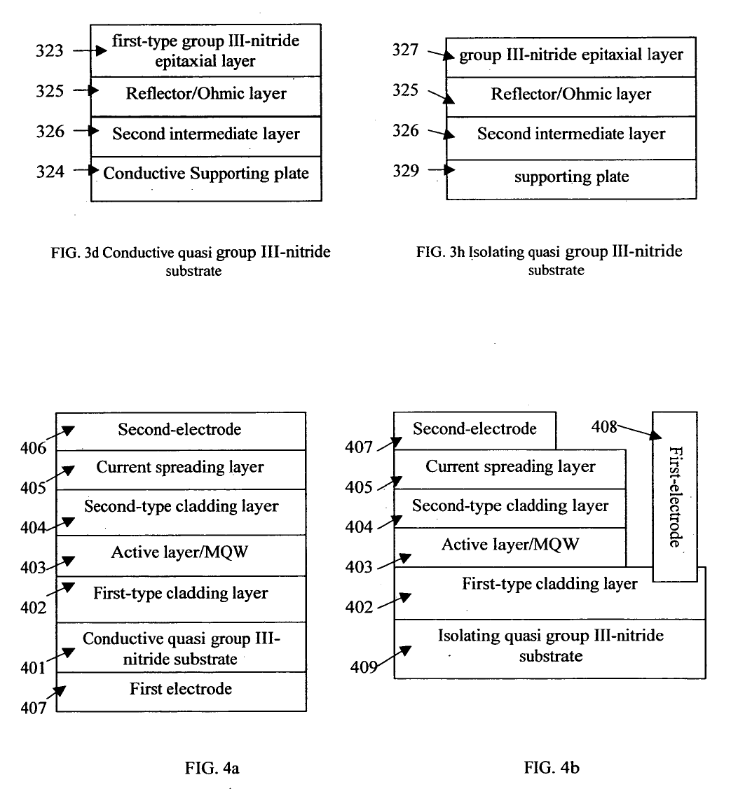

FIG. 4a shows an embodiment of vertical LEDs growing on a large area high quality electrically conductive quasi group III-nitride substrate.

In order to prevent electrically conductive quasi group III-nitride substrate 401 from bowing in the process of growing GaN based LEDs, a method selected from the followings may be employed: (1) non-rigidly holding electrically conductive quasi group III-nitride substrate 401 to a thermally conductive plate; (2) heating up the top surface of conductive quasi group III-nitride substrate 401 by an infrared heat source; (3) employing a thicker electrically conductive quasi group III-nitride substrate 301; (4) a combination thereof.

First-type cladding layer 402, active layer 403, second-type cladding layer 404, current spreading layer 405, and second-electrode 406 stack on the group III-nitride epitaxial layer of electrically conductive quasi group III-nitride substrate 401. The whole area of the other side of electrically conductive quasi group III-nitride substrate 401 is first-electrode 407.

FIG. 4b shows an embodiment of lateral GaN based LEDs growing on a large area high quality isolating quasi group III-nitride substrate. First-type cladding layer 402, active layer 403, second-type cladding layer 404, current spreading layer 405, and second-electrode 407 stack on one side of isolating quasi group III-nitride substrate 409. Etching a predetermined area of the epitaxial layer until first-type cladding layer 402 exposed, disposing first electrode 408 on first-type cladding layer 402.

Note that isolating quasi group III-nitride substrate 409 having higher thermal conductivity may be employed for growing high power lateral GaN based LEDs without need of employing flip chip technique for packaging. The so-grown lateral GaN based LEDs have higher light extract efficiency attribute to the reflector layer for some of configurations of isolating quasi group III-nitride substrates.

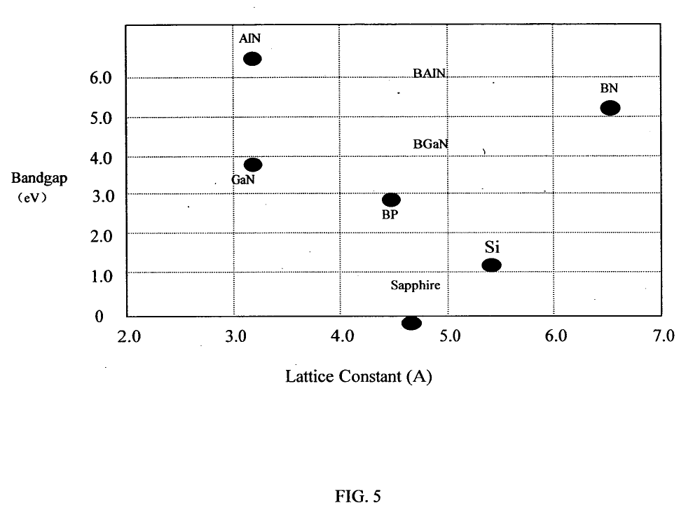

FIG. 5 shows a chart of bandgap vs lattice constants of silicon, sapphire, and binary and ternary of elements gallium (Ga), aluminum (Al), boron (B), phosphorus (P), nitrogen (N), comprising GaN, AlN, BAlN, BGaN, BP, BN. The exact values of bandgap and lattice constants of B.sub.xAl.sub.1-xN and B.sub.yGa.sub.1-yN depend on the values of “x” and “y”, respectively.

Although the description above contains many specifications, these should not be construed as limiting the scope of the present invention but as merely providing illustrations of some of the presently preferred embodiments of the present invention. Various modifications can be included in the present invention within a range which can be easily realized by those skilled in the art without departing from the spirit and principle of the scope of claims. Therefore the scope of the present invention should be determined by the claims and their legal equivalents, rather than by the examples given.

What is claim is:

1. A quasi group III-nitride substrate, comprises:
a substrate;
a group III-nitride epitaxial layer disposed on said substrate; wherein the structures of said group III-nitride epitaxial layer is selected from a group comprising single layer structure, multiple layer structure, and compositionally graded structure.

2. The quasi group III-nitride substrate of claim 1, wherein said substrate is an electrically conductive original growth substrate and selected from a group comprising electrically conductive silicon (Si) wafers; wherein said group III-nitride epitaxial layer is a first-type group III-nitride epitaxial layer; wherein the structure of said first-type group III-nitride epitaxial layer is selected from a group comprising single layer structure, multiple layer structure, and compositional graded structure; wherein the material system of each layer of said first-type group III-nitride epitaxial layer is selected from a group comprising a first-type of binary, ternary, and quaternary alloys of elements gallium (Ga), aluminum (Al), boron (B), indium (In), nitrogen (N); wherein said first-type of binary, ternary, and quaternary alloys comprising first-type GaN, first-type AlGaN, and first-type AlInGaN; wherein said first-type comprising n-type and p-type.

3. The quasi group III-nitride substrate of claim 2, further comprises an electrically conductive first intermediate layer disposed between said electrically conductive original growth substrate and said first-type group III-nitride epitaxial layer: wherein the strictures of said electrically conductive first intermediate layer comprising single layer structure and multiple layer structure; wherein the material system of each layer of said electrically conductive first intermediate layer being selected from a group comprising:
(a) a low melting point metal layer; wherein the material of said low melting point metal layer being selected from a group comprising cadmium (Cd), indium (In), tin (Sn); wherein said low melting point metal layer having melting point lower than the temperature of epitaxial growth;
(b) a high melting point metal layer; wherein the material of said high melting point metal layer being selected from a group comprising hafnium (Hf), scandium (Sc), titanium (Ti), vanadium (V), chromium (Cr), gold (Au), zirconium (Zr);
(c) combinations of (a) and (b).

4. The quasi group III-nitride substrate of claim 1, wherein said substrate is an electrically conductive supporting substrate; wherein the material of said electrically conductive supporting substrate being selected from a group comprising electrically conductive silicon wafers and thin metal layers; wherein the material of said thin metal layers being selected from a group comprising copper, gold, and aluminum; wherein said group III-nitride epitaxial layer is a first-type group III-nitride epitaxial layer; wherein the structure of said first-type group III-nitride epitaxial layer is selected from a group comprising single layer structure, multiple layer structure, and compositional graded structure; wherein the material system of each layer of said first-type group III-nitride epitaxial layer comprising a first-type of binary, ternary, and quaternary alloys of elements gallium (Ga), aluminum(Al), boron (B), indium (In), nitrogen (N); wherein said first-type of binary, ternary, and quaternary alloys comprising first-type GaN, first-type AlGaN, and first-type AlInGaN; wherein said first-type comprising n-type and p-type.

5. The quasi group III-nitride substrate of claim 4, further comprises a reflector/Ohmic layer disposed between said electrically conductive supporting substrate and said first-type group III-nitride epitaxial layer; wherein the structures of said reflector/Ohmic layer comprising single layer structure and multiple layer structure; wherein the material of each layer of said reflector/Ohmic layer being selected from a group comprising gold (Au), nickel (Ni), rhodium (Rh), titanium (Ti), platinum (Pt), copper (Cu), silver (Ag), vanadium (V), aluminum (Al), chromium (Cr), their alloys, and combinations thereof comprising Au/Ni/Ti.

6. The quasi group III-nitride substrate of claim 5, further comprises a second intermediate layer disposed between said electrically conductive supporting substrate and said reflector/Ohmic layer; wherein the material of said second intermediate layer being selected from a group comprising low melting point metals and low melting point alloys; wherein the material of said low melting point metal being selected from a group comprising indium (In), cadmium (Cd), and tin (Sn); wherein the material of said low melting point alloys being selected from a group comprising AuSn and AuGe.

7. The quasi group III-nitride substrate of claim 4, further comprises a second intermediate layer disposed between said electrically conductive supporting substrate and said first-type group III-nitride epitaxial layer; wherein the material of said second intermediate layer being selected from a group comprising low melting point metals and low melting point alloys; wherein the material of said low melting metal being selected from a group comprising indium (In), cadmium (Cd), and tin (Sn); wherein low melting point alloys being selected from a group comprising AuSn and AuGe.

8. The quasi group III-nitride substrate of claim 1, wherein said substrate is an original growth substrate; wherein said original growth substrate being selected from a group comprising silicon wafers; wherein the structure of said group III-nitride epitaxial layer is selected from a group comprising single layer structure, multiple layer structure, and compositional graded structure; wherein the material system of each layer of said group III-nitride epitaxial layer being selected from a group comprising binary, ternary, and quaternary alloys of elements gallium (Ga), aluminum (Al), indium (In), nitrogen (N); wherein said binary, ternary, and quaternary alloys comprising GaN, AlN, AlGaN, and AlInGaN.

9. The quasi group III-nitride substrate of claim 8, further comprises an electrically isolating first intermediate layer disposed between said original growth substrate and said group III-nitride epitaxial layer; wherein the structure of said electrically isolating first intermediate layer being selected from a group comprising single layer structure, multiple layer structure, and compositional graded structure; wherein the material of each layer of said electrically isolating first intermediate layer being selected from a group comprising:
(a) an epitaxial layer; wherein the structures of said epitaxial layer comprising single layer structure, multiple layer structure, and compositional graded structure; wherein the material system of each layer of said epitaxial layer being selected from a group comprises binary, ternary, and quaternary alloys of elements nitrogen (N), phosphorus (P), boron (B), silicon (Si), carbon (C), aluminum(Al); wherein said binary; ternary, and quaternary alloys comprising AlN, BP, 6H—SiC, 3C—SiC, BAlN, and combinations thereof;
(b) a low melting point metal layer; wherein the material of said low melting point metal layer being selected from a group comprising cadmium (Cd), indium (In), and tin (Sn); wherein said low melting point metal layer having melting point lower than the temperature of epitaxial growth;
(c) a high melting point metal layer; wherein the material of said high melting point metal layer being selected from a group comprising hafnium (Hf), scandium (Sc), titanium (Ti), vanadium (V), chromium (Cr), gold (Au), zirconium (Zr); wherein said high melting point metal layer having melting point higher than the temperature of epitaxial growth;
(d) a nitride layer of said high molting point metals; wherein the material system of said nitride layer being selected from a group comprising HfN, ScN, and TiN;
(e) combinations of (a), (b), (c), and (d).

10. The quasi group III-nitride substrate of claim 1, wherein said substrate is a supporting substrate; wherein said supporting substrate being selected from a group comprising silicon wafers and high thermal conductivity thin layers; wherein the material of said high thermal conductivity thin layers being selected from a group comprising AlN ceramic and tungsten; wherein the structure of said group III-nitride epitaxial layer being selected from a group comprising single layer structure, multiple layer structure, and compositional graded structure; wherein the material system of said group III-nitride epitaxial layer being selected from a group comprising binary, ternary, and quaternary alloys of elements gallium (Ga), aluminum (Al), indium (In), nitrogen (N); wherein said binary, ternary, and quaternary alloys comprising GaN, AlN, AlGaN, and AlInGaN.

11. The quasi group III-nitride substrate of claim 10, further comprises a reflector/Ohmic layer disposed between said supporting substrate and said group III-nitride epitaxial layer; wherein the structures of said reflector/Ohmic layer comprising single layer structure and multiple layer structure; wherein the material of each layer of said reflector/Ohmic layer being selected from a group comprising gold (Au), nickel (Ni), rhodium (Rh), titanium (Ti), platinum (Pt), copper (Cu), silver (Ag), vanadium(V), aluminum (Al), chromium (Cr), their alloy, and a Distributed Bragg Reflector (DBR).

12. The quasi group III-nitride substrate of claim 11, further comprises a second intermediate layer disposed between said supporting substrate and said reflector/Ohmic layer; wherein the material of said second intermediate layer being selected from a group comprising low melting point metals and low melting point alloys; wherein the material of said low melting point metal being selected from a group comprising indium (In), cadmium (Cd), tin (Sn); wherein the material of said low melting point alloys being selected from a group comprising AuSn and AuGe.

13. The quasi group III-nitride substrate of claim 10, further comprises a second intermediate layer disposed between said supporting substrate and said group III-nitride epitaxial layer, wherein the material of said second intermediate layer being selected from a group comprising low melting point metals and low melting point alloys; wherein the material of said low melting point metal being selected from a group comprising indium (In), cadmium (Cd), tin (Sn); wherein the material of said low melting point alloys being selected from a group comprising AuSn and AuGe.

14. A method for manufacturing quasi group III-nitride substrates, comprises process steps, in the order presented:
providing an original growth substrate;
disposing a first intermediate layer on said original growth substrate; wherein the material system of said first intermediate layer being selected from a group comprising an epitaxial layer, a low melting point metal layer, a high melting point metal layer, and nitrides of said high melting point metals, and combinations thereof; wherein said epitaxial layer being disposed by methods comprising MBE and MOCVD; wherein said low melting point metal layer being disposed by methods comprising vacuum evaporation; wherein said high melting point metal layer being disposed by methods comprising vacuum evaporation, MOCVD, and combinations thereof; said nitrides being disposed by methods comprising vacuum evaporation, nitriding, MOCVD, and combinations thereof;
disposing a group III-nitride epitaxial layer on said first intermediate layer; wherein said group III-nitride epitaxial layer being disposed by methods comprising MBE and MOCVD;

15. The method for manufacturing quasi group III-nitride substrates of claim 14, further comprises process steps:
disposing a supporting substrate on said group III-nitride epitaxial layer to form a bonded wafer; wherein said supporting substrate being disposed by methods being selected from a group comprising: (1) wafer bonding; (2) electroplating; (3) electro-less plating; (4) vacuum evaporation; and (5) combinations thereof;
removing said original growth substrate and said first intermediate layer from said bonded wafer so that said group III-nitride epitaxial layer exposed; wherein the methods of said removing of said original growth substrate and said first intermediate layer being selected from a group comprising precisely lapping/polishing, precisely grinding, selective dry and/or wet etching, heating up and shearing, and combinations thereof.

16. The method for manufacturing quasi group III-nitride substrates of claim 15, further comprises a process step: disposing a reflector/Ohmic layer between said supporting substrate and said group III-nitride epitaxial layer.

17. The method for manufacturing quasi group III-nitride substrates of claim 15, further comprises a process step: disposing a second intermediate layer between said group III-nitride epitaxial layer and said supporting substrate.

18. The method for manufacturing quasi group III-nitride substrate of claim 14, further comprises a process step; texturing one surface of said original growth substrate and disposing said first intermediate layer on the textured surface of said original growth substrate.

19. The method for manufacturing quasi group III-nitride substrate of claim 15, further comprises a process step: annealing said quasi group III-nitride substrate after removing said original growth substrate and said first intermediate layer.
